(19) United States
(12) Patent Application Publication
(10) Pub. No.: US 2008/0150542 A1
(43) Pub. Date: Jun. 26, 2008

(54) Battery analyzer in a battery pack and fixture

(76) Inventors: William Sapp, Poway, CA (US); Lance Chandler, Gig Harbor, WA (US); Jan Yang, Carlsbad, CA (US); Don Buckley, Poway, CA (US); Andrew Ng, Kwai Chung (HK)

Correspondence Address: Eastman & Associates, Suite 1800, 707 Broadway Street, San Diego, CA, 92101, US

(21) Appl. No.: 10/779,325

(22) Filed: Feb. 13, 2004

Related U.S. Application Data
(60) Provisional application No. 60/447,473, filed on Feb. 13, 2003.

(51) Int. Cl. G01R 31/36

(52) U.S. Cl. 324/435

(57) ABSTRACT

The Battery Analyzer in a Battery Pack and Fixture includes a portable handheld device containing multiple battery cells in a battery pack having a microprocessor or ASIC with companion circuitry for measuring the condition of the cell battery and manage the use of the battery taking into consideration the history of the battery, the condition of the various cells within the battery, the device the battery pack is being used in, and other factors. The condition of the battery pack may be displayed with an LCD display for direct user information, or may be relayed electromagnetically back to a base station through the transmitter portion of the device, such as a walkie talkie.

### RELATED APPLICATION

This application claims the benefit of priority to United States Provisional Patent Application No. 60/447,473 filed Feb. 13, 2003, and currently co-pending.

### FIELD OF THE INVENTION

The present invention relates generally to a portable system of analyzing cell batteries. More specifically, the present invention pertains to a small system capable of measuring and managing historical data and chemistry in cell batteries for electronic systems, and establishing criteria for an optimal charging of the cells.

### BACKGROUND OF THE INVENTION

This invention will replace larger bulky analyzers which are harder to use and are not portable. This invention will reduce the current difficulty in battery management, and show a battery fuel gage, monitor chemical breakdown, and usage of the battery pack.

### SUMMARY OF THE INVENTION

The present invention includes a portable handheld device containing multiple battery cells in a battery pack having a microprocessor or ASIC with companion circuitry for measuring the condition of the cell battery and manage the use of the battery taking into consideration the history of the battery, the condition of the various cells within the battery, the device the battery pack is being used in, and other factors. The condition of the battery pack may be displayed with an LCD display for direct user information, or may be relayed electromagnetically back to a base station through the transmitter portion of the device, such as a walkie talkie.

Novelties of the present invention include:
Embedded control with proprietary algorithms, including program memory and data memory, such as 8Kbytes of data.
High resolution LCD Display
Sub-functions, including:
   Serial number of device for tracking purposes
   Department identification for tracking and issuance of repair or retrieval issues
   Owner identification, including possible security password for user authentication
Mandatory initialization (such as warranty from date of service)
Chemistry of batteries contributes to the analysis provided for the pack
In circuit programming for updating battery information, re-programming of charging or discharging characteristics or protocol for specific uses.
Look-Up tables may include the following information regarding the particular application of the battery pack and device, and may include, as an example but not limitation:

TABLE 1

| Table | |
|---|---|
| Entry | Data or Information Available from Memory Table |
| Entry 1 | Charge and Discharge Profile for Battery Pack |
| Entry 2 | De-rating information on each of the cells in Pack |
| Entry 3 | Safety Constraints for particular cell type and/or |
| | chemistry and necessary Current/Voltage controls |
| Entry 4 | Manufacturer operating characteristics for each |
| | battery cell, including preferred charging |
| | characteristics. |
| Entry 5 | % of battery life remaining |

### DESCRIPTION OF A PREFERRED EMBODIMENT

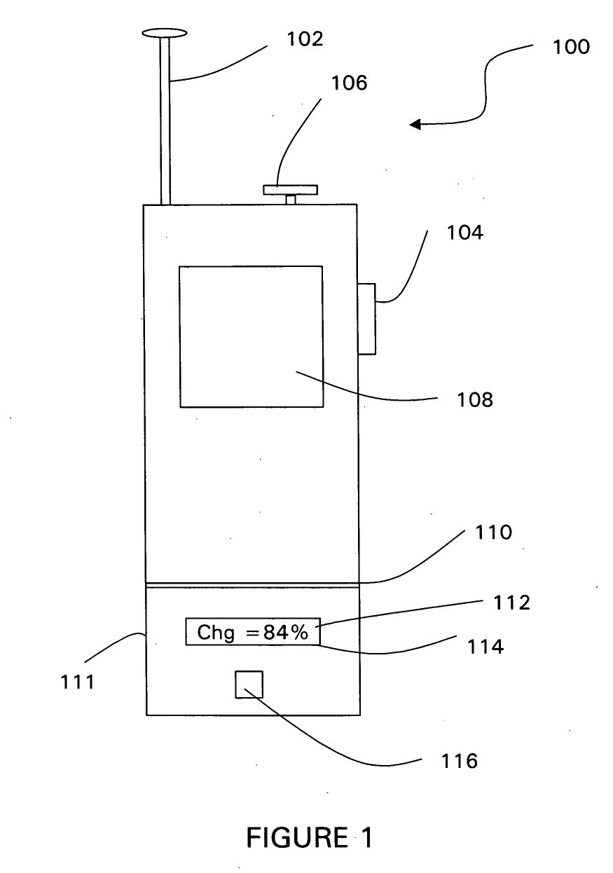

Referring to FIG. 1, a device incorporating the battery pack of the present invention is shown and generally designated 100. Device 100, such as a walkie-talkie, includes an antenna 102, a talk/listen button 104, a volume knob 106, a speaker 108, and at junction 110 is attached to a removable battery pack 111.

Removable battery pack 111 includes a display 114 displaying a message 112. In a preferred embodiment, pressing user interface button 116 may cause battery pack 111 to measure the cells (not shown this Figure) within the battery pack, and subsequent presses of button 116 may result in the performance of other diagnostic or data retrieval functions.

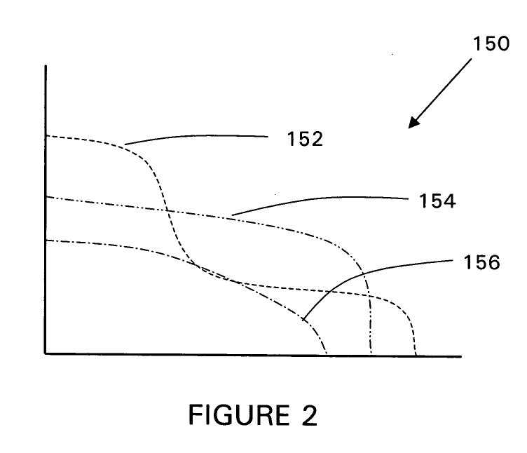

Referring to FIG. 2, a voltage vs. time plot of three (3) separate batteries within battery pack 111 are shown in plot 150. Specifically, a first cell is illustrated with line 152, a second cell is illustrated with line 154, and a third cell is illustrated with line 156. It is to be appreciated that three cells are depicted as being merely exemplary of a preferred embodiment, and that any number of cells may be incorporated therein.

The variable charge and discharge characteristics of separate battery cells within a battery pack often results in a less-than-maximized discharge period and a correspondingly unpredictable battery life. The present invention, however, monitors the charging and discharging of the various battery cells and as a result, may provide an instantaneous “fuel gage” indicating the electrical capacity remaining within the battery pack and available for use.

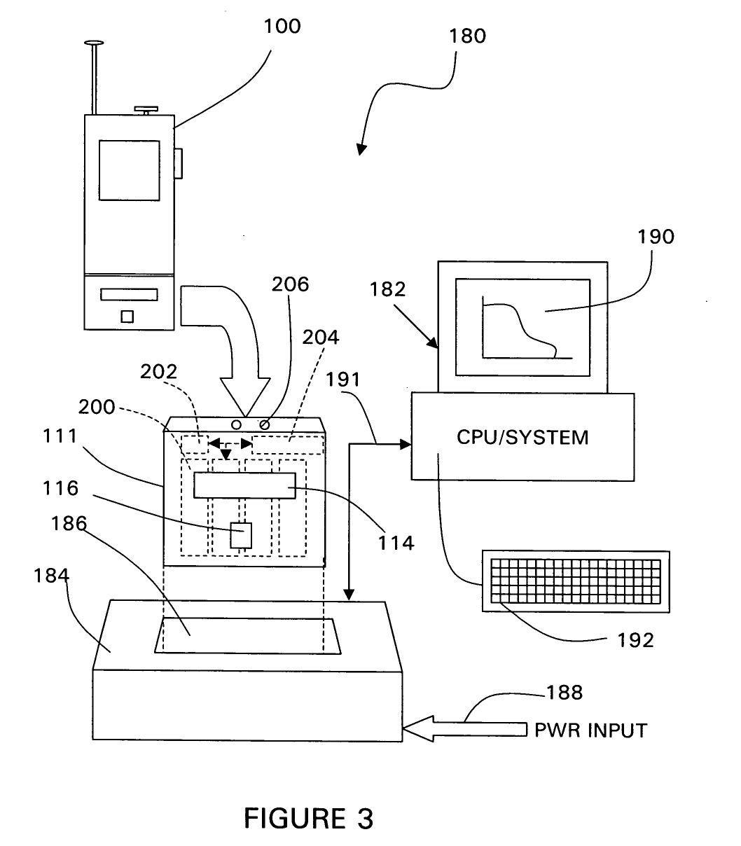

FIG. 3 illustrates a charging system of the present invention, including the device 100 and a fixture 180. Fixture 180 includes a CPU/System 182, such as a x86 processor-based computer, and a base station 184 formed with a receiver 186 for receiving battery pack 111 of device 100. Receiver 186 may receive a power input 188, or may be provided power via interconnect 191 from CPU/System 182. Receiver 184 provides a charging current and data connection with battery pack 111 via terminals (not shown) as is known in the art.

Interconnect 191, in a preferred embodiment, may be any communication cable for transmitting and receiving one or more data channels from the receiver 184, such as a USB cable. Power may also be supplied in interconnect 191. The particular communication protocol used to communicate between CPU 182 and battery pack 111 may be a standard single-wire communication protocol, such as standard RS-232, or it may be proprietary.

Battery pack 111 includes a number of battery cells 200 that are electrically connected to a processor 204, such as a microcontroller, microprocessor, application specific semiconductor (ASIC) or discrete logic elements. A memory 202 may contain the look up table identified above in Table 1, as well as other data related to the battery pack 111, and the operational program for providing the analysis of battery cells 200 and displaying such analysis results on display 114, as well as communicating these results to CPU 182 along interconnect 191.

Battery pack 111 may be removed from device 100. In order to provide an electrical connection between battery pack 111 and device 100, a pair of electrical contacts 206 may be provided. It is to be appreciated that additional electrical connections may be provided to exchange information between device 100 and battery pack 111, or such information exchange may occur through contacts 206 using techniques known in the art.

Because of the ability to closely monitor the capacities within each of the cells 200 within the battery pack 111, the processor 204 within the battery pack 111 may perform an algorithm which provides for the mid-level correction of the output voltage of the battery pack 111. This correction provides for an extended life of the battery pack at an acceptable voltage level for the device 100.

CPU/System 182 includes a display 190 for providing information to an operator of system 180, such as the graph shown in FIG. 3. In some instances, this information may include data related to the charging, discharging, period of discharging, period of charging, or other aspects of reliability for the battery pack 111.

A graphic user interface may be implemented in a preferred embodiment of battery pack 111 that, in addition to the message shown in FIG. 1, provides additional information related to the battery pack 111. This information may include information in the table below, shown as an example and not as a limitation.

| Number of Presses | |
|---|---|
| of Button 116 | Display Information |
| 1 | Remaining life or charge of Battery Pack |
| 2 | Serial Number of Battery Pack |
| 3 | Error Condition “Cell #2 Voltage Low” |
| 4 | Date of last charging cycle |

1. A Battery Analyzer in a Battery Pack, comprising:
a display;
a user interface; and
a means for performing diagnostic and data retrieval functions.
